(19) United States
(12) Patent Application Publication
(10) Pub. No.: US 2015/0357991 A1
(43) Pub. Date: Dec. 10, 2015

(54) RECEIVING DEVICE AND WIRELESS POWER TRANSFER APPARATUS

(71) Applicant: KABUSHIKI KAISHA TOYOTA JIDOSHOKKI, Kariya-shi, Aichi-ken (JP)

(72) Inventors: Takuma ONO, Kariya-shi (JP); Hiroki TOGANO, Kariya-shi (JP); Yuichi TAGUCHI, Kariya-shi (JP); Atsushi YAMAGUCHI, Kariya-shi (JP)

(73) Assignee: KABUSHIKI KAISHA TOYOTA JIDOSHOKKI, Kariya-shi, Aichi-ken (JP)

(21) Appl. No.: 14/654,728

(22) PCT Filed: Dec. 16, 2013
(86) PCT No.: PCT/JP2013/083579

§ 371 Date: Jun. 22, 2015

(30) Foreign Application Priority Data
Dec. 25, 2012 (JP) 2012-281575

(51) Int. Cl. H03H 7/40; H01F 38/14; H02J 7/02; H02J 5/00

(52) U.S. Cl. CPC H03H 7/40; H02J 5/005; H01F 38/14; H02J 7/025

(57) ABSTRACT

A receiving device includes: a secondary coil capable of wirelessly receiving alternating current power; a load having an impedance that varies in accordance with a value of input power; a variable impedance conversion unit located between the secondary coil and the load; a plurality of adjusting resistors located at an output side of the variable impedance conversion unit, wherein the adjusting resistors respectively have resistances that are fixed regardless of the value of the input power and differ from each other; and a switch that switches a subject supplied with power output from the variable impedance conversion unit to one of the load and the adjusting resistors. When the impedance of the variable impedance conversion unit is variably controlled, the subject supplied with the power output from the variable impedance conversion unit is switched to one of the adjusting resistors.

### TECHNICAL FIELD

The present invention relates to a receiving device and wireless power transfer apparatus.

### BACKGROUND ART

In the prior art, a known wireless power transfer apparatus including no power cords and no power transfer cables uses, for example, magnetic field resonance. For example, Japanese Laid-Open Patent Publication No. 2009-106136 describes a wireless power transfer apparatus including a supply device that has an alternating current power supply and a primary coil. The primary coil receives alternating current power from the alternating current power supply. The wireless power transfer apparatus includes a receiving device that has a secondary coil capable of performing magnetic field resonance with the primary coil. When the primary coil and the secondary coil perform magnetic field resonance, the alternating current power is transferred from the supply device to the receiving device. The alternating current power received by the receiving device is used to charge a battery located in the receiving device.

### PRIOR ART DOCUMENT

### Patent Document

Patent Document 1: Japanese Laid-Open Patent Publication No. 2009-106136

### SUMMARY OF THE INVENTION

### Problems that are to be Solved by the Invention

To improve the transfer efficiency, an impedance conversion unit may be used to perform a conversion and obtain the desired impedance. In such a case, a vehicle battery may be configured to have impedance that varies in accordance with the value of input direct current power. In such a configuration, variations in the value of direct current power, which is input to the vehicle battery, vary the impedance of the vehicle battery. When the impedance obtained through a conversion performed by the impedance conversion unit is deviated from the desired impedance, problems may occur, such as a decrease in the transfer efficiency.

In this regard, a variable impedance conversion unit, which has variable impedance, may be used as the impedance conversion unit. When the value of direct current power input to the vehicle battery varies, the variable impedance conversion unit variably controls the impedance. In the above variable control, use of alternating current power having the same value as that used for charging the vehicle battery would cause power loss and loads on elements and thus is not preferred. However, if the value of the power is decreased, the impedance of the vehicle battery would vary as described above. Thus, even if the above variable control is performed, problems, such as a decrease in the transfer efficiency, would occur when charging the vehicle battery.

The above problems commonly occur in a receiving device and a wireless power transfer apparatus that includes a load having impedance varying in accordance with the value of the input power.

### Means for Solving the Problem

It is an object of the present invention to provide a receiving device and a wireless power transfer apparatus that are capable of variably controlling impedance of a variable impedance conversion unit.

One aspect of the present disclosure is a receiving device capable of wirelessly receiving alternating current power from a supply device including a primary coil that receives the alternating current power. The receiving device includes a secondary coil, a load, a variable impedance conversion unit, a plurality of adjusting resistors, and a switch. The secondary coil is capable of wirelessly receiving the alternating current power from the primary coil. The load has impedance that varies in accordance with a value of input power. The variable impedance conversion unit has variable impedance and is located between the secondary coil and the load. The adjusting resistors are located at an output side of the variable impedance conversion unit. The adjusting resistors respectively have resistances that are fixed regardless of the value of the input power and differ from each other. The switch switches a subject supplied with power output from the variable impedance conversion unit to one of the load and the adjusting resistors. When the impedance of the variable impedance conversion unit is variably controlled, the subject supplied with the power output from the variable impedance conversion unit is switched to one of the adjusting resistors.

In this embodiment, when variably controlling the impedance of the variable impedance conversion unit, the subject supplied with the power output from the variable impedance conversion unit is switched to one of the adjusting resistors having different resistances. This varies impedance of the variable impedance conversion unit located at the output side. Thus, even when the impedance of the load varies, the output-side impedance of the variable impedance conversion unit may follow the impedance of the load.

The resistance of each adjusting resistor is fixed regardless of the value of the input power. This allows the output-side impedance of the variable impedance conversion unit to be close to the impedance of the load. Additionally, the value of alternating current power may vary between when performing the variable control and when supplying the power to the load.

Therefore, the impedance of the variable impedance conversion unit may be variably controlled in a preferred manner.

In one embodiment, the supply device supplies first alternating current power and second alternating current power to the secondary coil. The first alternating current power and the second alternating current power are each power that may be input to the load. The first alternating current power and the second alternating current power have different values. The adjusting resistors include a first adjusting resistor and a second adjusting resistor. The first adjusting resistor has a resistance that is the same as the impedance of the load when the first alternating current power is input to the load. The second adjusting resistor has a resistance that is the same as the impedance of the load when the second alternating current power is input to the load.

In this embodiment, when the subject supplied with the power output from the variable impedance conversion unit is the first adjusting resistor, the output-side impedance of the variable impedance conversion unit corresponds to the impedance of the load when the first alternating current power is input to the load. Under this situation, when the impedance of the variable impedance conversion unit is variably controlled, the impedance of the variable impedance conversion unit may have a value that corresponds to the situation in which the first alternating current power is input to the load.

In the same manner, when the subject supplied with the power output from the variable impedance conversion unit is the second adjusting resistor, the output-side impedance of the variable impedance conversion unit corresponds to the impedance of the load when the second alternating current power is input to the load. Under this situation, when the impedance of the variable impedance conversion unit is variably controlled, the impedance of the variable impedance conversion unit may have a value that corresponds to the situation in which the second alternating current power is input to the load.

In one embodiment, when the impedance of the variable impedance conversion unit is variably controlled before the first alternating current power is input to the load, the subject supplied with the power output from the variable impedance conversion unit is switched to the first adjusting resistor. When the impedance of the variable impedance conversion unit is variably controlled before the second alternating current power is input to the load, the subject supplied with the power output from the variable impedance conversion unit is switched to the second adjusting resistor. In one embodiment, the load includes a rectifying unit and a battery. The rectifying unit includes a diode and rectifies input alternating current power to direct current power. The battery receives the direct current power, which has been rectified by the rectifying unit.

As described above, when the load is configured to receive each alternating current power, the impedance of the variable impedance conversion unit may be variably controlled in a preferred manner.

Another aspect of the present disclosure is a wireless power transfer apparatus including an alternating current power supply capable of outputting multiple kinds of alternating current powers that have different values, a primary coil that receives the alternating current power, a secondary coil capable of receiving alternating current power that has been received by the primary coil, and a load having an impedance that varies in accordance with a value of input power. The wireless power transfer apparatus further includes a variable impedance conversion unit, a plurality of adjusting resistors, a switch, and a switch control unit. The variable impedance conversion unit has variable impedance and is located between the alternating current power supply and the load. The adjusting resistors are located at an output side of the variable impedance conversion unit. The adjusting resistors respectively have resistances that are fixed regardless of the value of the input power, and the resistances differ from each another. The switch switches a subject supplied with power output from the variable impedance conversion unit to one of the load and the adjusting resistors. The switch control unit controls the switch to switch the subject supplied with the power output from the variable impedance conversion unit to one of the adjusting resistors when the impedance of the variable impedance conversion unit is variably controlled.

In this configuration, when the impedance of the variable impedance conversion unit is variably controlled, the subject supplied with the power output from the variable impedance conversion unit is switched to one of the adjusting resistors having different resistances. This varies the output-side impedance of the variable impedance conversion unit. Thus, even when the impedance of the load varies, the output-side impedance of the variable impedance conversion unit may follow the impedance of the load.

The resistance of each adjusting resistor is fixed regardless of the value of the input power. This allows the output-side impedance of the variable impedance conversion unit to be close to the impedance of the load. Additionally, when performing the above variable control, the alternating current power supply may output alternating current power the value of which differs from the value of alternating current power when supplying the power to the load.

Thus, the impedance of the variable impedance conversion unit may be variably controlled in a preferred manner.

In one embodiment, the alternating current power output from the alternating current power supply includes first alternating current power and second alternating current power. The first alternating current power and the second alternating current power have different values. The adjusting resistors include a first adjusting resistor and a second adjusting resistor. The first adjusting resistor has a resistance that is the same as the impedance of the load when the first alternating current power is input to the load. The second adjusting resistor has a resistance that is the same as the impedance of the load when the second alternating current power is input to the load.

In this embodiment, when the subject supplied with the power output from the variable impedance conversion unit is the first adjusting resistor, the output-side impedance of the variable impedance conversion unit corresponds to the impedance of the load when the first alternating current power is input to the load. Under this situation, when the impedance of the variable impedance conversion unit is variably controlled, the impedance of the variable impedance conversion unit may have a value that corresponds to the situation in which the first alternating current power is input to the load.

In the same manner, when the subject supplied with the power output from the variable impedance conversion unit is the second adjusting resistor, the output-side impedance of the variable impedance conversion unit corresponds to the impedance of the load when the second alternating current power is input to the load. Under this situation, when the impedance of the variable impedance conversion unit is variably controlled, the impedance of the variable impedance conversion unit may have a value that corresponds to the situation in which the second alternating current power is input to the load.

In one embodiment, the alternating current power supply outputs alternating current power having a smaller value than the first alternating current power and the second alternating current power when the variable impedance conversion unit is variably controlled.

In one embodiment, the switch control unit controls the switch to switch the subject supplied with the power output from the variable impedance conversion unit to the load when the alternating current power supply outputs the first alternating current power or the second alternating current power.

As described above, when the alternating current power is configured to output each alternating current power, the impedance of the variable impedance conversion unit may be variably controlled in a preferred manner.

Other aspects and advantages of the disclosure will become apparent from the following description, taken in conjunction with the accompanying drawings, illustrating by way of example the principles of the disclosure.

### BRIEF DESCRIPTION OF THE DRAWINGS

Novel features of the present disclosure will become apparent from the accompanying claims. The invention, together with objects and advantages thereof, may best be understood by reference to the following description of the presently preferred embodiments together with the accompanying drawings in which:

FIG. 1 is a circuit diagram showing the electrical structure of a receiving deice and a wireless power transfer apparatus;

FIG. 2 is a flowchart showing the charging process performed by a vehicle-side controller;

FIG. 3 is a flowchart showing the process for adjusting a constant; and

FIG. 4 is a time chart showing temporal changes in the value of high frequency power output from a high frequency power supply.

### EMBODIMENTS OF THE INVENTION

One embodiment of a receiving device and a wireless power transfer apparatus (wireless power transfer system) will now be described.

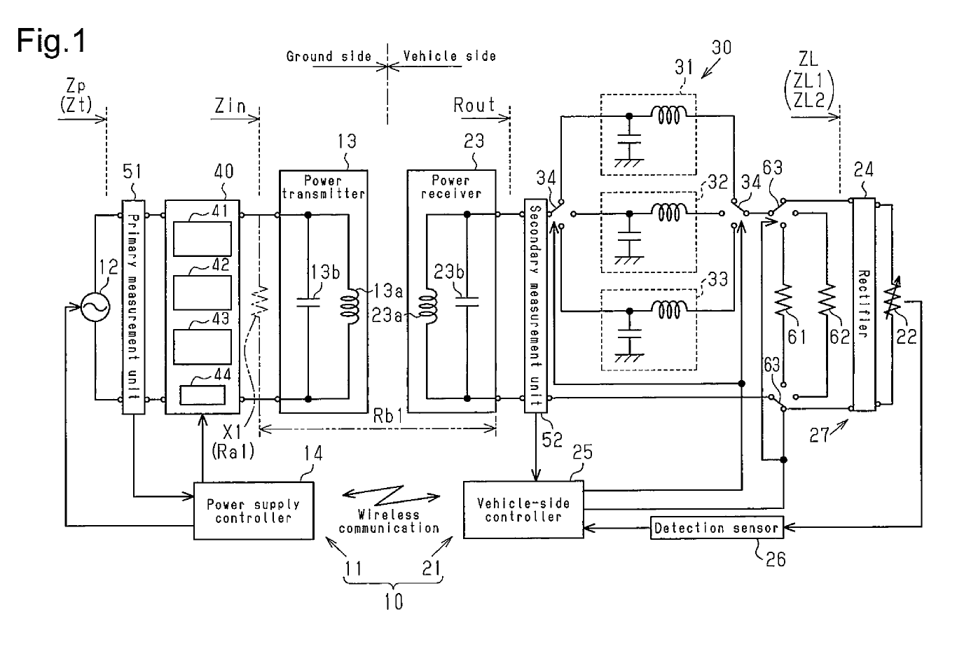

As shown in FIG. 1, a wireless power transfer apparatus 10 includes a ground-side device 11, which is located on the ground, and a vehicle-side device 21, which is mounted on a vehicle. The ground-side device 11 corresponds to a supply device (primary device). The vehicle-side device 21 corresponds to a receiving device (secondary device).

The ground-side device 11 includes a high frequency power supply 12 (alternating current power supply), which is capable of outputting high frequency power (alternating current power) of a predetermined frequency. The high frequency power supply 12 is configured to be capable of using the system power and outputting multiple kinds of high frequency power having different values.

High frequency power output from the high frequency power supply 12 is wirelessly transferred to the vehicle-side device 21 and input to a vehicle battery 22 (storage) located in the vehicle-side device 21. More specifically, the wireless power transfer apparatus 10 includes a power transmitter 13 (primary resonance circuit) located in the ground-side device 11 and a power receiver 23 (secondary resonance circuit) located in the vehicle-side device 21, which function to transfer power between the ground-side device 11 and the vehicle-side device 21.

The power transmitter 13 and the power receiver 23, which have the same structure, are configured to be capable of performing magnetic field resonance. More specifically, the power transmitter 13 includes a resonance circuit formed by a primary coil 13a and a primary capacitor 13b, which are connected in parallel. The power receiver 23 includes a resonance circuit formed by a secondary coil 23a and a secondary capacitor 23b, which are connected in parallel. The power transmitter 13 and the power receiver 23 are set to have the same resonance frequency.

In this configuration, when high frequency power is input to the power transmitter 13 (primary coil 13a), the power transmitter 13 and the power receiver 23 (secondary coil 23a) perform magnetic field resonance. Consequently, the power receiver 23 receives some of the energy from the power transmitter 13. That is, the power receiver 23 receives high frequency power from the power transmitter 13.

The vehicle-side device 21 includes a rectifier 24 (rectifying unit) having a semiconductor element (diode). The rectifier 24 rectifies high frequency power, which is received by the power receiver 23, to direct current power. The rectifier 24 operates when receiving a predetermined threshold voltage. The direct current power, which has been rectified by the rectifier 24, is input to the vehicle battery 22. The vehicle battery 22, which includes battery cells connected in series, is charged when receiving the direct current power. For the sake of brevity, an input terminal of the rectifier 24 to the vehicle battery 22 may be referred to as a load 27.

The ground-side device 11 includes a power supply controller 14, which controls the ground-side device 11 including the high frequency power supply 12. The power supply controller 14 controls activation and deactivation of the high frequency power supply 12 and the value of high frequency power output from the high frequency power supply 12. For example, in a charging control sequence in which the vehicle battery 22 is charged, the power supply controller 14 controls the high frequency power supply 12 so that the high frequency power supply 12 outputs high frequency power of (three) different values, namely, adjusting power, normal charging power, and push charging power. The adjusting power is high frequency power that is output before starting to charge the vehicle battery 22. The normal charging power is high frequency power used for the normal charging of the vehicle battery 22. The push charging power is high frequency power used for the push charging, which compensates variations in capacities of the battery cells included in the vehicle battery 22. The relationship in power level is expressed as adjusting power<push charging power<normal charging power. Thus, multiple kinds of high frequency power having different values, which are supplied from the ground-side device 11 to the power receiver 23 (secondary coil 23a), may be input to the load 27.

The vehicle-side device 21 includes a vehicle-side controller 25, which is capable of performing wireless communication with the power supply controller 14. The wireless power transfer apparatus 10 controls the power transfer by exchanging information between the controllers 14, 25.

The vehicle-side device 21 includes a detection sensor 26 that detects a charge amount (state of charge, SOC) of the vehicle battery 22. The detection sensor 26 transmits detection results to the vehicle-side controller 25. This allows the vehicle-side controller 25 to acknowledge the charge amount of the vehicle battery 22.

The vehicle-side device 21 includes a secondary variable impedance conversion unit 30, which has a variable constant (impedance). The secondary variable impedance conversion unit 30 is located in a power transfer line from the power receiver 23 to the vehicle battery 22, more specifically, between the power receiver 23 and the rectifier 24. High frequency power, which is received by the power receiver 23, may be input to a location downstream of the rectifier 24 through the secondary variable impedance conversion unit 30.

In the same manner, the ground-side device 11 includes a primary variable impedance conversion unit 40, which has a variable constant (impedance). The primary variable impedance conversion unit 40 is located in the power transfer line from the high frequency power supply 12 to the power transmitter 13. High frequency power, which is output from the high frequency power supply 12, is input to the power transmitter 13 through the primary variable impedance conversion unit 40. The constant (impedance) may be referred to as a conversion ratio, inductance, or capacitance.

The inventors have found that the real part of impedance from an output terminal of the power receiver 23 (secondary coil 23a) to the vehicle battery 22 contributes to transfer efficiency between the power transmitter 13 and the power receiver 23. More specifically, the inventors have found that the real part of the impedance from the output terminal of the power receiver 23 to the vehicle battery 22 includes a specific resistance Rout that increases the transfer efficiency to be relatively higher than other resistances. In other words, the inventors have found that the real part of the impedance from the output terminal of the power receiver 23 to the vehicle battery 22 includes the specific resistance Rout (second resistance) that increases the transfer efficiency to be higher than a predetermined resistance (first resistance).

More specifically, if a virtual load X1 were to be arranged at an input terminal of the power transmitter 13, the specific resistance Rout would be √(Ra1×Rb1), where the resistance of the virtual load X1 is represented by Ra1, and the resistance from the power receiver 23 (more specifically, output terminal of the power receiver 23) to the virtual load X1 is represented by Rb1.

Based on the above findings, the secondary variable impedance conversion unit 30 performs an impedance conversion so that the impedance from the output terminal of the power receiver 23 to the vehicle battery 22 (impedance of the input terminal of the secondary variable impedance conversion unit 30) approaches (preferably, equals to) the specific resistance Rout.

The value of high frequency power output from the high frequency power supply 12 is dependent on impedance Zp from an output terminal of the high frequency power supply 12 to the vehicle battery 22 (impedance of an input terminal of the primary variable impedance conversion unit 40).

In this configuration, when the impedance from the output terminal of the power receiver 23 to the vehicle battery 22 is close to the specific resistance Rout, the primary variable impedance conversion unit 40 impedance-converts impedance Zin from the input terminal of the power transmitter 13 to the vehicle battery 22 so that the high frequency power supply 12 outputs high frequency power of the desired value.

For example, the impedance Zp from the output terminal of the high frequency power supply 12 to the vehicle battery 22 that allows the high frequency power supply 12 to output the high frequency power of the value suited for charging is referred to as a suitable input charging impedance Zt. In this case, the primary variable impedance conversion unit 40 impedance-converts the impedance Zin from the input terminal of the power transmitter 13 to the vehicle battery 22 so that the impedance Zp from the output terminal of the high frequency power supply 12 to the vehicle battery 22 approaches (preferably, equals to) the suitable input charging impedance Zt.

In other words, the high frequency power supply 12 is configured to be capable of outputting the desired values of high frequency power, namely, the adjusting power, the normal charging power, and the push charging power, when the impedance Zp from the output terminal of the high frequency power supply 12 to the vehicle battery 22 is the suitable input charging impedance Zt.

The impedance of the vehicle battery 22 varies in accordance with the value of input direct current power. Thus, when the value of high frequency power output from the high frequency power supply 12 varies, impedance ZL of the load 27 including the vehicle battery 22 varies in accordance with the value of the input power.

The specific resistance Rout is determined by the configuration of the power transmitter 13 and the power receiver 23 (e.g., shapes and inductances of the coils 13a, 23a, and capacitances of the capacitors 13b, 23b) and the relative position of the power transmitter 13 and the power receiver 23. Thus, when the power transmitter 13 and the power receiver 23 are displaced from a predetermined reference position, that is, the relative position of the power transmitter 13 and the power receiver 23 varies, the specific resistance Rout varies.

In this regard, the wireless power transfer apparatus 10 can follow variations in the relative position of the power transmitter 13 and the power receiver 23 and variations in the impedance ZL of the load 27. This aspect will now be described together with the specific configuration of each of the variable impedance conversion units 30, 40.

The secondary variable impedance conversion unit 30 includes a plurality of (e.g., three) secondary impedance converters 31 to 33 (secondary impedance conversion units). The secondary impedance converters 31 to 33 are arranged in parallel. The secondary impedance converters 31 to 33 each include an L-type LC circuit. The secondary impedance converters 31 to 33 have different constants. Thus, the secondary variable impedance conversion unit 30 may function with a plurality of (three) constants.

The secondary variable impedance conversion unit 30 includes relays 34. The relays 34 switch a connected subject of the power receiver 23 and the rectifier 24 (vehicle battery 22) to one of the secondary impedance converters 31 to 33. The relays 34 are located at two opposite sides of the secondary variable impedance conversion unit 30. The switching of the relays 34 switches the secondary impedance converter that receives high frequency power from the power receiver 23.

In the same manner as the secondary variable impedance conversion unit 30, the primary variable impedance conversion unit 40 includes a plurality of (e.g., three) primary impedance converters 41 to 43 (primary impedance conversion units). The primary variable impedance conversion unit 40 includes a relay 44. The relay 44 switches a connected subject of the high frequency power supply 12 and the power transmitter 13 to one of the primary impedance converters 41 to 43. The primary impedance converters 41 to 43 each include a reversed-L-type LC circuit.

The ground-side device 11 includes a primary measurement unit 51 located between the high frequency power supply 12 and the primary variable impedance conversion unit 40. The primary measurement unit 51 measures a voltage waveform and a current waveform of the high frequency power output from the high frequency power supply 12 and transmits a measurement result to the power supply controller 14.

The vehicle-side device 21 includes a secondary measurement unit 52 located between the power receiver 23 and the secondary variable impedance conversion unit 30. The secondary measurement unit 52 measures a voltage waveform and a current waveform of the high frequency power received by the power receiver 23 and transmits a measurement result to the vehicle-side controller 25.

The vehicle-side device 21 includes a plurality of (more specifically, two) adjusting resistors 61, 62 located at an output side of the secondary variable impedance conversion unit 30. The adjusting resistors 61, 62 are each located between the power receiver 23 and the load 27, more specifically, between the secondary variable impedance conversion unit 30 and the rectifier 24. The adjusting resistors 61, 62 are arranged in parallel.

The adjusting resistors 61, 62 each have resistance (impedance) that is fixed regardless of the value of input power. The adjusting resistors 61, 62 have different resistances. The resistances of the adjusting resistors 61, 62 are each set in correspondence with the value of high frequency power output from the high frequency power supply 12. For example, when the high frequency power supply 12 is outputting the normal charging power, the impedance ZL of the load 27 may be referred to as a first load impedance ZL1. In this case, the resistance of the first adjusting resistor 61 is set to be the same as the first load impedance ZL1. When the high frequency power supply 12 is outputting the push charging power, the impedance ZL of the load 27 may be referred to as a second load impedance ZL2. In this case, the resistance of the second adjusting resistor 62 is set to be the same as the second load impedance ZL2.

Since the high frequency power output from the high frequency power supply 12 corresponds to the high frequency power input to the load 27, “high frequency power output from the high frequency power supply 12” may be referred to as “high frequency power input to the load 27”. In other words, the resistances of the adjusting resistors 61, 62 are set in correspondence with values of high frequency power input to the load 27. The normal charging power corresponds to “first alternating current power”. The push charging power corresponds to “second alternating current power”.

The vehicle-side device 21 includes switch relays 63, which function as switches. The switch relays 63 switch a connected subject of the secondary variable impedance conversion unit 30 to one of the adjusting resistors 61, 62, and the load 27. The connected subject of the secondary variable impedance conversion unit 30 may be referred to as the subject supplied with the high frequency power output from the secondary variable impedance conversion unit 30. The relays 34 and the switch relays 63 determine the subject supplied with the high frequency power received by the power receiver 23.

In the charging process, in which the charging control sequence is performed, the vehicle-side controller 25 controls the switch relays 63 to switch the connected subject of the secondary variable impedance conversion unit 30. The controllers 14, 25 respectively control the relays 34, 44 based on the measurement results of the measurement units 51, 52. This variably controls the constants of the variable impedance conversion units 30, 40.

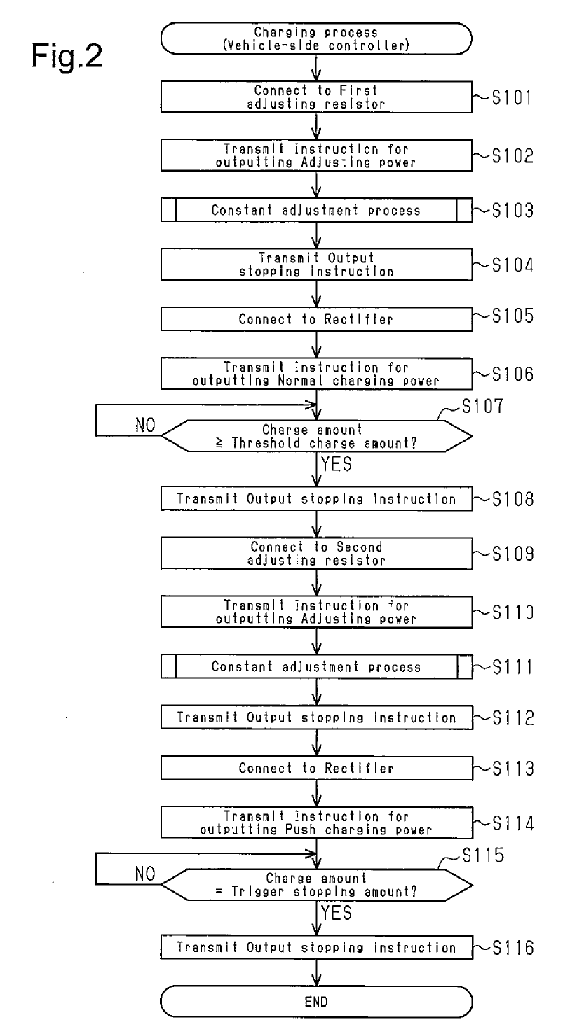

The charging process performed by the vehicle-side controller 25 will now be described with reference to FIG. 2. For the sake of brevity, before the charging is started, the charge amount of the vehicle battery 22 is less than a threshold charge amount.

In step S101, the vehicle-side controller 25 switches the switch relays 63 so that the connected subject of the secondary variable impedance conversion unit 30 is set to the first adjusting resistor 61. In step S102, the vehicle-side controller 25 transmits an instruction to the power supply controller 14 so that the high frequency power supply 12 outputs the adjusting power. When receiving the instruction, the power supply controller 14 controls the high frequency power supply 12 so that the high frequency power supply 12 outputs the adjusting power.

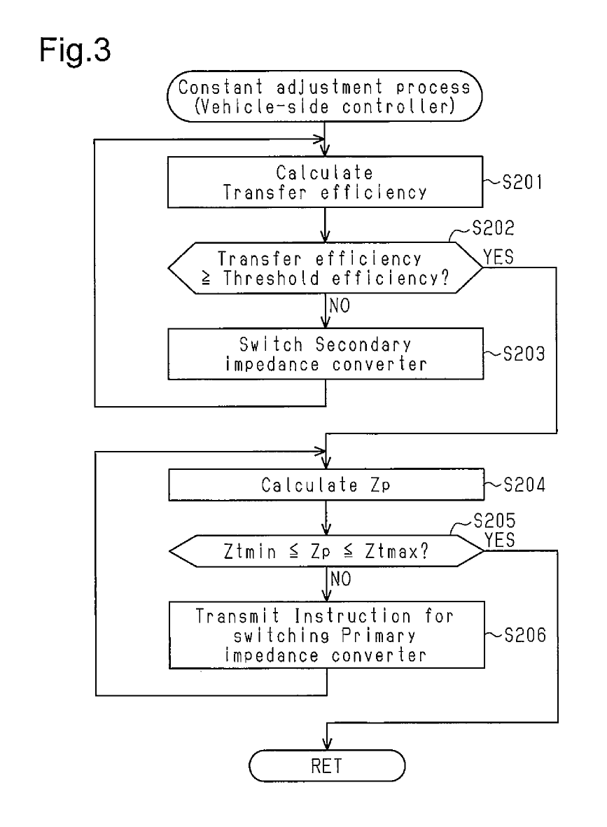

In step S103, the vehicle-side controller 25 performs a constant adjustment process, in which the constants of the variable impedance conversion units 30, 40 are adjusted. The constant adjustment process will now be described using the flowchart of FIG. 3.

In step S201, the vehicle-side controller 25 calculates the transfer efficiency based on the measurement results of the measurement units 51, 52. In step S202, the vehicle-side controller 25 determines whether or not the transfer efficiency calculated in step S201 is greater than or equal to predetermined threshold efficiency.

When the transfer efficiency is less than the threshold efficiency, the impedance from the output terminal of the power receiver 23 to the vehicle battery 22 may be deviated from the specific resistance Rout due to the deviation in positions of the power transmitter 13 and the power receiver 23 or the like. In this case, in step S203, the vehicle-side controller 25 variably controls the constant of the secondary variable impedance conversion unit 30. More specifically, the vehicle-side controller 25 controls the relays 34 to switch the secondary impedance converter that receives the high frequency power from the power receiver 23. Then, steps S201 to S203 are performed until the transfer efficiency reaches or exceeds the threshold efficiency.

Although not shown in the drawings, the transfer efficiency may remain less than the threshold efficiency even when switching to all of the secondary impedance converters 31 to 33. In this case, an abnormality notification may be issued to indicate the occurrence of an abnormality, and the charging process may then be terminated.

When the transfer efficiency is greater than or equal to the threshold efficiency, in step 204, the vehicle-side controller 25 obtains the measurement result of the primary measurement unit 51 from the power supply controller 14 and calculates the impedance Zp from the output terminal of the high frequency power supply 12 to the vehicle battery 22.

In step S205, the vehicle-side controller 25 determines whether or not the impedance Zp from the output terminal of the high frequency power supply 12 to the vehicle battery 22 is close to the suitable input charging impedance Zt. More specifically, the vehicle-side controller 25 determines whether or not the impedance Zp from the output terminal of the high frequency power supply 12 to the vehicle battery 22 is in a predetermined range (Ztmin to Ztmax). The predetermined range (Ztmin to Ztmax) includes the suitable input charging impedance Zt.

When the impedance Zp is out of the range, this indicates that the value of the high frequency power output from the high frequency power supply 12 is deviated from the desired value of power. In this case, in step S206, the vehicle-side controller 25 variably controls the constant of the primary variable impedance conversion unit 40. More specifically, the vehicle-side controller 25 transmits a switch instruction to the power supply controller 14 to switch the primary impedance converter that receives the high frequency power. When receiving the switch instruction, the power supply controller 14 controls the relay 44 to switch the primary impedance converter that receives the high frequency power. Subsequently, in step S204, the vehicle-side controller 25 again calculates the impedance Zp from the output terminal of the high frequency power supply 12 to the vehicle battery 22. Then, the vehicle-side controller 25 determines whether or not the calculated impedance Zp is in the range. When the calculated impedance Zp is out of the range, the primary impedance converter that receives the high frequency power is switched.

Even when the connected subject is switched to all of the primary impedance converters 41 to 43, the impedance Zp from the output terminal of the high frequency power supply 12 to the vehicle battery 22 may remain out of the range. In this case, an abnormality notification may be issued to indicate the occurrence of an abnormality, and the charging process may then be terminated.

When the impedance Zp from the output terminal of the high frequency power supply 12 to the vehicle battery 22 is in the range, it is determined that the variable control of the constants of the variable impedance conversion units 30, 40 has been finished. Thus, the vehicle-side controller 25 makes an affirmative determination in step S205. In this case, the constant adjustment process is terminated, and the charging process is resumed.

Returning to the description of the charging process (FIG. 2), after the constant adjustment process of step S103 is finished, instep S104, the vehicle-side controller 25 transmits an instruction for stopping the output of high frequency power to the power supply controller 14. When receiving the output stopping instruction, the power supply controller 14 stops outputting high frequency power from the high frequency power supply 12.

Then, in step S105, the vehicle-side controller 25 controls the switch relays 63 so that the connected subject of the secondary variable impedance conversion unit 30 is set to the rectifier 24. In step S106, the vehicle-side controller 25 transmits an instruction to the power supply controller 14 so that the high frequency power supply 12 outputs the normal charging power. When receiving the instruction, the power supply controller 14 controls the high frequency power supply 12 so that the normal charging power is output. Consequently, the charging of the vehicle battery 22 is started.

In step S107, the vehicle-side controller 25 periodically obtains the current charge amount of the vehicle battery 22 from the detection sensor 26 and continues the normal charging until the charge amount reaches or exceeds the threshold charge amount. When the charge amount reaches or exceeds the threshold charge amount, the vehicle-side controller 25 makes an affirmative determination in step S107 and proceeds to step S108. In step S108, the vehicle-side controller 25 transmits the instruction for stopping the output of high frequency power to the power supply controller 14.

In step S109, the vehicle-side controller 25 controls the switch relays 63 so that the connected subject of the secondary variable impedance conversion unit 30 is set to the second adjusting resistor 62. In step S110, the vehicle-side controller 25 transmits an instruction to the power supply controller 14 so that the high frequency power supply 12 outputs the adjusting power. In step S111, the vehicle-side controller 25 performs the constant adjustment process. Here, the process is the same as step S103 and thus will not be described.

After the constant adjustment process is performed, in step S112, the vehicle-side controller 25 transmits the instruction for stopping the output of high frequency power to the power supply controller 14. In step S113, the vehicle-side controller 25 controls the switch relays 63 so that the connected subject of the secondary variable impedance conversion unit 30 is set to the rectifier 24. In step S114, the vehicle-side controller 25 transmits an instruction to the power supply controller 14 so that the high frequency power supply 12 outputs the push charging power. When receiving the instruction, the power supply controller 14 controls the high frequency power supply 12 so that the push charging power is output.

In step S115, the push charging continues until the charge amount reaches a predetermined trigger stopping amount. When the charge amount has reached the trigger stopping amount, the vehicle-side controller 25 makes an affirmative determination in step S115 and proceeds to step S116. In step S116, the vehicle-side controller 25 transmits the instruction for stopping the output of high frequency power to the power supply controller 14 and terminates the charging process. When receiving the output stopping instruction, the power supply controller 14 stops the high frequency power supply 12 from outputting high frequency power. This terminates the charging of the vehicle battery 22.

The operation of the present embodiment will now be described together with temporal changes in the value of high frequency power output from the high frequency power supply 12.

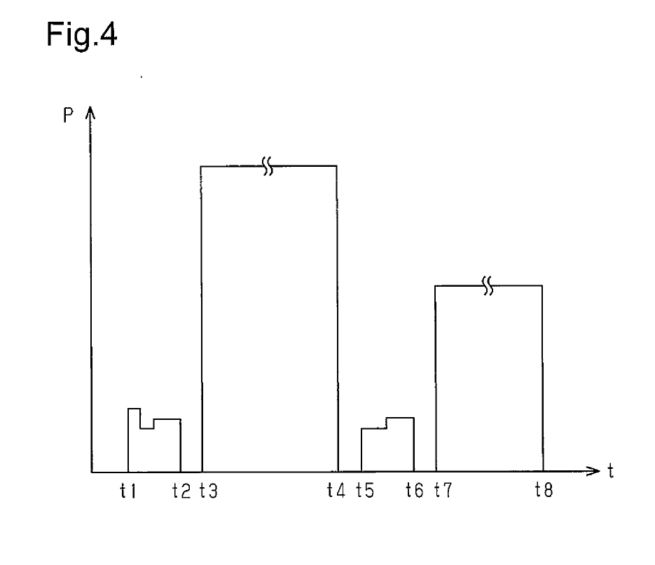

As shown in FIG. 4, at timing tl, when the connected subject of the secondary variable impedance conversion unit 30 is the first adjusting resistor 61, the adjusting power is output. Under this situation, the constants of the variable impedance conversion units 30, 40 are variably controlled. The variable control of the constant of the primary variable impedance conversion unit 40 causes variations in the adjusting power.

At timing t2, when finishing the variable control of the constants of the variable impedance conversion units 30, 40, the output of the adjusting power is stopped. Then, after the connected subject of the secondary variable impedance conversion unit 30 is switched to the load 27, at timing t3, the normal charging power is output.

In this case, as described above, the resistance of the first adjusting resistor 61 is set to be the same as the first load impedance ZL1. Thus, even when the connected subject of the secondary variable impedance conversion unit 30 is switched from the first adjusting resistor 61 to the load 27, and the value of high frequency power output from the high frequency power supply 12 during adjustment differs from the value of power during the normal charging, output-side impedance of the secondary variable impedance conversion unit 30 (impedance that is subject to conversion) remains unvaried. This maintains high transfer efficiency (impedance from the output terminal of the power receiver 23 to the vehicle battery 22 is close to the specific resistance Rout) and obtains the desired value of high frequency power (i.e., value of the normal charging power), which is output from the high frequency power supply 12.

At timing t4, when the charge amount of the vehicle battery 22 reaches the threshold charge amount, the output of high frequency power is temporarily stopped. Then, the connected subject of the secondary variable impedance conversion unit 30 is switched to the second adjusting resistor 62. At timing t5, the adjusting power is output. Subsequently, the variable control is performed on the constants of the variable impedance conversion units 30, 40.

At timing t6, the output of the adjusting power is stopped. Then, after the connected subject of the secondary variable impedance conversion unit 30 is switched to the load 27, at timing t7, the push charging power is output.

In this case, as described above, the resistance of the second adjusting resistor 62 is set to be the same as the second load impedance ZL2. Thus, even when the connected subject of the secondary variable impedance conversion unit 30 is switched from the second adjusting resistor 62 to the load 27, and the value of high frequency power output from the high frequency power supply 12 during adjustment differs from the value of power during the push charging, the output-side impedance of the secondary variable impedance conversion unit 30 (impedance that is subject to conversion) remains unvaried. This maintains high transfer efficiency (impedance from the output terminal of the power receiver 23 to the vehicle battery 22 is close to the specific resistance Rout) and obtains the desired value of high frequency power (i.e., value of the push charging power), which is output from the high frequency power supply 12.

At timing t8, when the charge amount of the vehicle battery 22 has reached the trigger stopping amount, the output of the push charging power is stopped.

The present embodiment has the advantages described below.

(1) The secondary variable impedance conversion unit 30 is located at the output side of the power receiver 23. The secondary variable impedance conversion unit 30 is configured to perform impedance conversion so that the impedance from the output terminal of the power receiver 23 to the vehicle battery 22 approaches the predetermined value (specific resistance Rout). The secondary variable impedance conversion unit 30 has the variable constant. This improves the transfer efficiency.

The ground-side device 11 includes the primary variable impedance conversion unit 40 between the high frequency power supply 12 and the power transmitter 13. The primary variable impedance conversion unit 40 is configured so that the impedance Zp from the output terminal of the high frequency power supply 12 to the vehicle battery 22 approaches the desired impedance (e.g., suitable input charging impedance Zt). The primary variable impedance conversion unit 40 has the variable constant. Thus, high frequency power may be appropriately input to the load 27.

In this configuration, the adjusting resistors 61, 62 are located at the output side of the secondary variable impedance conversion unit 30. The resistances of the adjusting resistors 61, 62 are fixed regardless of the value of input power and different from each other. The switch relays 63 are arranged to switch the connected subject of the secondary variable impedance conversion unit 30 to one of the adjusting resistors 61, 62, and the load 27. The switch relays 63 are configured to switch the connected subject of the secondary variable impedance conversion unit 30 to one of the adjusting resistors 61, 62 when variably controlling the constants of the variable impedance conversion units 30, 40. Consequently, when variably controlling the constants of the variable impedance conversion units 30, 40, there is no need to consider variations in the impedance ZL of the load 27. Thus, the variable control may be easily performed on the constants of the variable impedance conversion units 30, 40.

The adjusting resistors 61, 62 allow the output-side impedance of the secondary variable impedance conversion unit 30 to be variable when variably controlling the constants of the variable impedance conversion units 30, 40. The resistances of the adjusting resistors 61, 62 do not vary in accordance with the value of input power. This allows the value of power during charging to differ from the value of power during adjustment. Thus, the adjusting power, which has a smaller value than the high frequency power used for charging (normal charging power and push charging power), may be used for variable control of the constants of the variable impedance conversion units 30, 40 that follows the variations in the impedance ZL of the load 27.

With regard to the primary variable impedance conversion unit 40, the adjusting resistors 61, 62 allow the output-side impedance of the primary variable impedance conversion unit 40 to be variable when performing the above variably control of the constants.

(2) The resistance of each of the adjusting resistors 61, 62 is set in correspondence with the value of high frequency power output from the high frequency power supply 12. More specifically, the first adjusting resistor 61 is set to be the same as the first load impedance ZL1. The first load impedance ZL1 is the impedance ZL of the load 27 when the high frequency power supply 12 outputs the normal charging power (when the normal charging power is input to the load 27). The second adjusting resistor 62 is set to be the same as the second load impedance ZL2. The second load impedance ZL2 is the impedance ZL of the load 27 when the high frequency power supply 12 outputs the push charging power (when the push charging power is input to the load 27).

The constants of the variable impedance conversion units 30, 40 may be variably controlled before the normal charging is performed (normal charging power is output). In this case, the vehicle-side controller 25 controls the switch relays 63 so that the connected subject of the secondary variable impedance conversion unit 30 is set to the first adjusting resistor 61. The constants of the variable impedance conversion units 30, 40 may be variably controlled before the push charging is performed (push charging power is output). In this case, the vehicle-side controller 25 controls the switch relays 63 so that the connected subject of the secondary variable impedance conversion unit 30 is set to the second adjusting resistor 62. Thus, the output-side impedance of the secondary variable impedance conversion unit 30 subtly varies even when the value of high frequency power output from the high frequency power supply 12 during adjustment differs from the value of high frequency power output from the high frequency power supply 12 during charging (normal charging or push charging). This limits decreases in the transfer efficiency and the like.

(3) In the wireless power transfer apparatus 10, the rectifier 24 and the power receiver 23 are located at opposite sides of the adjusting resistors 61, 62. Additionally, the switch relays 63 switch the connected subject of the secondary variable impedance conversion unit 30 (subject supplied with the high frequency power output from the secondary variable impedance conversion unit 30) to one of the adjusting resistors 61, 62, and the load 27. Thus, the constants of the variable impedance conversion units 30, 40 may be variably controlled using the adjusting power, which has a further smaller value.

More specifically, if the adjusting resistors 61, 62 are located downstream of the rectifier 24 (e.g., between the rectifier 24 and the vehicle battery 22), high frequency power would need to pass through the rectifier 24 in order to reflect the impedance located downstream of the rectifier 24. That is, high frequency power transmitted to the rectifier 24 would need to have a voltage capable of activating at least a diode included in the rectifier 24.

In this regard, when the present embodiment variably controls the constants of the variable impedance conversion units 30, 40, the connected subject of the secondary variable impedance conversion unit 30 is one of the adjusting resistors 61, 62, which include no semiconductor elements, such as diodes. Thus, the present embodiment has no voltage limitation such as that described above, thereby decreasing the value of the adjusting power. This reduces power loss when variably controlling the constants of the variable impedance conversion units 30, 40.

(4) The wireless power transfer apparatus 10 is configured to variably control the constant of the primary variable impedance conversion unit 40 after variably controlling the constant of the secondary variable impedance conversion unit 30. This avoids unnecessary variable control.

More specifically, for example, if the constant of the secondary variable impedance conversion unit 30 is variably controlled after the constant of the primary variable impedance conversion unit 40 is variably controlled, the variable control performed on the constant of the secondary variable impedance conversion unit 30 would cause deviations in the impedance Zp from the output terminal of the high frequency power supply 12 to the vehicle battery 22. Consequently, variable control would need to be performed again on the constant of the primary variable impedance conversion unit 40.

In this regard, the present embodiment first variably controls the constant of the secondary variable impedance conversion unit 30. This avoids the above problem, thereby simplifying the control.

The embodiment may be modified as follows.

In the embodiment, the ground-side device 11 and the vehicle-side device 21 include the variable impedance conversion units 30, 40. However, one of the variable impedance conversion units 30, 40 may be omitted. One of the variable impedance conversion units 30, 40 may have a fixed constant.

Each adjusting resistor may be arranged at the output terminal of the primary variable impedance conversion unit 40, that is, between the primary variable impedance conversion unit 40 and the power transmitter 13. Also, a switch relay may be arranged to switch the subject supplied with the high frequency power output from the primary variable impedance conversion unit 40, to one of the adjusting resistors and the power transmitter 13. In this case, it is preferred that the resistance of each adjusting resistor is set in correspondence with the impedance Zin from the input terminal of the power transmitter 13 to the vehicle battery 22.

In the embodiment, the ground-side device 11 includes the single variable impedance conversion unit 30. The vehicle-side device 21 includes the single variable impedance conversion unit 40. However, there is no limit to such a configuration. For example, in the embodiment, the ground-side device 11 and the vehicle-side device 21 may each include two or more variable impedance conversion units.

The embodiment includes two kinds of high frequency power, which is output during charging, namely, the normal charging power and the push charging power. However, there is no limit to such a configuration. For example, three or more kinds of high frequency power may be used. In this case, it is preferred that three or more adjusting resistors are arranged. Other kinds of high frequency power include quick charging power, which has a larger value than the normal charging power.

In the embodiment, the variable impedance conversion units 30, 40 are each configured to include a plurality of impedance converters having different constants. However, there is no limit to such a configuration. For example, the variable impedance conversion units 30, 40 may each include an LC circuit having at least one of a variable capacitor, in which the capacitance is variable, and a variable inductor, in which the inductance is variable.

In the embodiment, the primary impedance convertors 41 to 43 each include a reversed-L-type LC circuit. The secondary impedance converters 31 to 33 each include an L-type CL circuit. However, any specific circuit configuration may be used. For example, a n-type or a T-type may be used.

In the embodiment, the secondary impedance converters 31 to 33 and the primary impedance converters 41 to 43 each include an LC circuit. However, any specific configuration may be used. For example, the secondary impedance converters 31 to 33 and the primary impedance converters 41 to 43 may each include a transformer.

In the embodiment, the charging process is performed by the vehicle-side controller 25. However, there is no limit to such a configuration. For example, the charging process may be performed by the power supply controller 14.

Each adjusting resistor may be located between the rectifier 24 and the vehicle battery 22. In this case, it is preferred that each adjusting resistor is set in correspondence with the impedance of the vehicle battery 22.

In the embodiment, when the connected subject of the secondary variable impedance conversion unit 30 is switched, the output of high frequency power is stopped. However, there is no limit to such a configuration. For example, the above switching may be performed without stopping the output of high frequency power.

The primary variable impedance conversion unit 40 may be configured to impedance-convert the impedance Zin from the input terminal of the power transmitter 13 to the vehicle battery 22 so that the power factor is improved (reactance of predetermined impedance approaches zero).

Instead of (or in addition to) the secondary variable impedance conversion unit 30, a DC/DC converter may be located between the rectifier 24 and the vehicle battery 22. The DC/DC converter includes a switching element, which periodically performs switching (on and off). Adjusting resistors may be arranged between the DC/DC converter and the vehicle battery 22. Also, a switch relay may be arranged to switch a connected subject of the DC/DC converter to one of the adjusting resistors and the vehicle battery 22. In this case, the vehicle-side device 21 may be configured to adjust impedance of an input terminal of the DC/DC converter by adjusting the on-off duty ratio of the switching element. Through the adjustment, the impedance from the output terminal of the power receiver 23 to the vehicle battery 22 approaches the specific resistance Rout. In this case, the DC/DC converter corresponds to a “variable impedance conversion unit”. The vehicle battery 22 corresponds to a “load”. In other words, the “load” receives high frequency power from the power receiver 23 (secondary coil 23a) or direct current power, which is the rectified high frequency power.

When an electric power source is employed as the high frequency power supply 12, the electric power may be used to impedance-match the variable impedance conversion units 30, 40. More specifically, the primary variable impedance conversion unit 40 may be configured to impedance-convert the impedance Zin from the input terminal of the power transmitter 13 to the vehicle battery 22 so that the impedance Zp from the output terminal of the high frequency power supply 12 to the vehicle battery 22 matches output impedance of the high frequency power supply 12. The secondary variable impedance conversion unit 30 may be configured to impedance-convert the impedance ZL of the load 27 so that the impedance from the output terminal of the power receiver 23 to the vehicle battery 22 matches the impedance from the output terminal of the power receiver 23 to the high frequency power supply 12.

In this configuration, the wireless power transfer apparatus 10 may be configured so that the primary measurement unit 51 measures reflected wave power directed from the power transmitter 13 toward the high frequency power supply 12, and the secondary measurement unit 52 measures reflected wave power directed from the secondary variable impedance conversion unit 30 to the high frequency power supply 12. It is preferred that the controllers 14, 25 variably control the constants of the variable impedance conversion units 30, 40 so that each reflected wave power is reduced. In the above configuration, it is preferred that the variable control is simultaneously performed on the constants of the variable impedance conversion units 30, 40.

In the embodiment, the resonance frequency of the power transmitter 13 is set to be the same as the same resonance frequency of the power receiver 23. However, there is no limit to such a configuration. The power transmitter 13 and the power receiver 23 may have different resonance frequencies within a range in which power transfer is allowed.

In the embodiment, the power transmitter 13 and the power receiver 23 have the same configuration. However, there is no limit to such a configuration. The configuration of the power transmitter 13 may differ from the configuration of the power receiver 23.

The capacitors 13b, 23b may be omitted from the embodiment. In this case, the power transmitter 13 and the power receiver 23 perform magnetic field resonance using parasitic capacitances of the coils 13a, 23a.

In the embodiment, magnetic field resonance is used to perform wireless power transfer. However, there is no limit to such a configuration. Electromagnetic induction may be used.

In the embodiment, the wireless power transfer apparatus 10 is applied to a vehicle. However, there is no limit to such a configuration. The wireless power transfer apparatus 10 may be applied to another apparatus. For example, the wireless power transfer apparatus 10 may be used to charge a battery of a mobile phone.

In the embodiment, the load 27 includes the vehicle battery 22. However, there is no limit to such a configuration. For example, another component may be included. The load 27 only needs to be configured to have the impedance ZL that varies in accordance with the value of input power.

The high frequency power supply 12 may be one of an electric power source, a voltage source, and a current source.

The embodiment includes the high frequency power supply 12. However, there is no limit to such a configuration. The high frequency power supply 12 may be omitted. In this case, the system power may be directly connected to the primary variable impedance conversion unit 40.

The power transmitter 13 may be configured to include a resonance circuit formed by the primary coil 13a and the primary capacitor 13b and a primary coupling coil, which is coupled to the resonance circuit through electromagnetic induction. In the same manner, the power receiver 23 may be configured to include a resonance circuit formed by the secondary coil 23a and the secondary capacitor 23b and a secondary coupling coil, which is coupled to the resonance circuit through electromagnetic induction.

### DESCRIPTION OF REFERENCE SYMBOLS

10 wireless power transfer apparatus, 12 high frequency power supply, 13a primary coil, 21 vehicle-side device (receiving device), 22 vehicle battery, 23a secondary coil, 25 vehicle-side controller (switch control unit), 30,40 variable impedance conversion unit, 61, 62 adjusting resistor, 63 switch relay (switch)

1. A receiving device capable of wirelessly receiving alternating current power from a supply device including a primary coil that receives the alternating current power, the receiving device comprising:
a secondary coil capable of wirelessly receiving the alternating current power from the primary coil;
a load having an impedance that varies in accordance with a value of input power;
a variable impedance conversion unit having a variable impedance and located between the secondary coil and the load;
a plurality of adjusting resistors located at an output side of the variable impedance conversion unit, wherein the adjusting resistors respectively have resistances that are fixed regardless of the value of the input power and differ from each other; and
a switch that switches a subject supplied with power output from the variable impedance conversion unit to one of the load and the adjusting resistors, wherein
when the impedance of the variable impedance conversion unit is variably controlled, the subject supplied with the power output from the variable impedance conversion unit is switched to one of the adjusting resistors.

2. The receiving device according to claim 1, wherein:
the supply device supplies first alternating current power and second alternating current power to the secondary coil;
the first alternating current power and the second alternating current power are each power that may be input to the load;
the first alternating current power and the second alternating current power have different values;
the adjusting resistors include a first adjusting resistor and a second adjusting resistor;
the first adjusting resistor has a resistance that is the same as the impedance of the load when the first alternating current power is input to the load; and
the second adjusting resistor has a resistance that is the same as the impedance of the load when the second alternating current power is input to the load.

3. The receiving device according to claim 2, wherein:
when the impedance of the variable impedance conversion unit is variably controlled before the first alternating current power is input to the load, the subject supplied with the power output from the variable impedance conversion unit is switched to the first adjusting resistor; and
when the impedance of the variable impedance conversion unit is variably controlled before the second alternating current power is input to the load, the subject supplied with the power output from the variable impedance conversion unit is switched to the second adjusting resistor.

4. The receiving device according to claim 1, wherein the load includes
a rectifying unit that includes a diode and rectifies input alternating current power to direct current power, and
a battery that receives the direct current power, which has been rectified by the rectifying unit.

5. A wireless power transfer apparatus including an alternating current power supply capable of outputting multiple kinds of alternating current powers that have different values, a primary coil that receives the alternating current power, a secondary coil capable of receiving alternating current power that has been received by the primary coil, and a load having an impedance that varies in accordance with a value of input power, the wireless power transfer apparatus comprising:
a variable impedance conversion unit having a variable impedance and located between the alternating current power supply and the load;
a plurality of adjusting resistors located at an output side of the variable impedance conversion unit, wherein the adjusting resistors respectively have resistances that are fixed regardless of the value of the input power, and the resistances differ from each another;
a switch that switches a subject supplied with power output from the variable impedance conversion unit to one of the load and the adjusting resistors; and
a switch control unit that controls the switch to switch the subject supplied with the power output from the variable impedance conversion unit to one of the adjusting resistors when the impedance of the variable impedance conversion unit is variably controlled.

6. The wireless power transfer apparatus according to claim 5, wherein:
the alternating current power output from the alternating current power supply includes first alternating current power and second alternating current power;
the first alternating current power and the second alternating current power have different values;
the adjusting resistors include a first adjusting resistor and a second adjusting resistor;
the first adjusting resistor has a resistance that is the same as the impedance of the load when the first alternating current power is input to the load; and
the second adjusting resistor has a resistance that is the same as the impedance of the load when the second alternating current power is input to the load.

7. The wireless power transfer apparatus according to claim 6, wherein the alternating current power supply outputs alternating current power having a smaller value than the first alternating current power and the second alternating current power when the variable impedance conversion unit is variably controlled.

8. The wireless power transfer apparatus according to claim 6, wherein the switch control unit controls the switch to switch the subject supplied with the power output from the variable impedance conversion unit to the load when the alternating current power supply outputs the first alternating current power or the second alternating current power.
